(19) United States
(12) Patent Application Publication
(10) Pub. No.: US 2025/0385138 A1
(43) Pub. Date: Dec. 18, 2025

(54) METHOD FOR MANUFACTURING CHIPS

(71) Applicant: DISCO CORPORATION, Tokyo (JP)

(72) Inventors: Marina MURAKAMI, Tokyo (JP); Shin TABATA, Tokyo (JP); Tsuyoshi HATA, Tokyo (JP); Kazuya MANTANI, Tokyo (JP)

(73) Assignee: DISCO CORPORATION, Tokyo (JP)

(21) Appl. No.: 19/231,855

(22) Filed: Jun. 9, 2025

(30) Foreign Application Priority Data
Jun. 12, 2024 (JP) 2024-094854
Jul. 31, 2024 (JP) 2024-124101
Apr. 22, 2025 (JP) 2025-070435

(51) Int. Cl. H01L 21/78

(52) U.S. Cl. CPC H01L 21/78

(57) ABSTRACT

A chip manufacturing method for manufacturing a plurality of chips by dividing a substrate along predetermined dicing lines includes forming a protective film on a surface of the substrate; removing the protective film along the predetermined dicing lines; dividing the substrate into the plurality of chips along the predetermined dicing lines by performing plasma-etching using the protective film remaining on the surface of the substrate as a mask; and chamfering peripheral regions of the chips by performing plasma-etching using the protective film as a mask.

### CROSS REFERENCE TO RELATED APPLICATION

This application is based upon and claims the benefit of priority from the prior Japanese Patent Application No. 2024-094854 filed on Jun. 12, 2024; the prior Japanese Patent Application No. 2024-124101 filed on Jul. 31, 2024, and the prior Japanese Patent Application No. 2025-070435 filed on Apr. 22, 2025, the entire contents of which are incorporated herein by reference.

### FIELD

The present disclosure relates to a method for manufacturing chips.

### BACKGROUND

A method for manufacturing chips, where a substrate such as a semiconductor wafer is divided into a plurality of chips by being irradiated with a laser beam or cut with a blade, has been suggested in, for example, Japanese Patent Application Laid-Open Publication No. 2017-220602. Edge portions of the chips divided from the substrate in the manner as above may typically form corners.

The corners at the edge portions of the chips are often relatively weak in their structure against impact. Therefore, in a dicing process where the substrate is divided into the plurality of chips, when adjacent chips collide with each other, there may be a risk that the chips are damaged at the edge portions and further.

### SUMMARY

An object of the present disclosure is to provide a method for manufacturing chips, where strength of the divided chips may be improved and damage to the chips may be suppressed.

According to an aspect of the present disclosure, a chip manufacturing method for manufacturing a plurality of chips by dividing a substrate along predetermined dicing lines includes forming a protective film on a surface of the substrate; removing the protective film along the predetermined dicing lines; dividing the substrate into the plurality of chips along the predetermined dicing lines by performing plasma-etching using the protective film remaining on the surface of the substrate as a mask; and chamfering peripheral regions of the chips by performing plasma-etching using the protective film as a mask.

Optionally, a condition for plasma-etching in dividing the substrate into the plurality of chips and a condition for plasma-etching in chamfering peripheral regions of the chips may be different.

Optionally, the chip manufacturing method may further include removing a part of the protective film remaining on the surface of the substrate so as to vary a removal amount of the protective film within a plane of the chips in a thickness direction in a manner such that a thickness of the protective film in the peripheral regions decreases from an inner side toward an outer side of each chip, before chamfering peripheral regions of the chips.

According to another aspect of the present disclosure, a chip manufacturing method for manufacturing a plurality of chips by dividing a substrate along predetermined dicing lines includes dividing the substrate along the predetermined dicing lines to obtain the plurality of chips; forming a protective film on surfaces of the plurality of chips; and chamfering peripheral regions of the chips by performing plasma-etching using the protective film as a mask.

According to the aspects of the present disclosure, the peripheral regions of the chips obtained by dividing the substrate are chamfered by plasma-etching. Thereby, durability of the edge portions of the chips may be improved, and damages may be suppressed.

### BRIEF DESCRIPTION OF THE DRAWINGS

FIG. 1 is a flowchart illustrating a method for manufacturing chips according to a first embodiment.

FIG. 2 is a diagram illustrating a protective film forming step.

FIG. 3 is a diagram illustrating a protective film removing step.

FIG. 4 is another diagram illustrating the protective film removing step.

FIG. 5 is a diagram showing a substrate after the protective film removing step.

FIG. 6 is a diagram illustrating a dicing step.

FIG. 7 is another diagram illustrating the dicing step.

FIG. 8 is a flowchart of a Bosch process in the dicing step.

FIG. 9 is a diagram illustrating a chamfering step.

FIG. 10 is a diagram showing the chips having been chamfered in the chamfering step.

FIG. 11 is a flowchart illustrating a method for manufacturing chips according to a second embodiment.

FIG. 12 is a flowchart illustrating a method for manufacturing chips according to a third embodiment.

FIG. 13 is a flowchart illustrating a method for manufacturing chips according to a fourth embodiment.

FIG. 14 is a flowchart illustrating a method for manufacturing chips according to a fifth embodiment.

FIG. 15 is a diagram illustrating a first protective film forming step.

FIG. 16 is a diagram illustrating a first thinned portion forming step.

FIG. 17 is a diagram showing a substrate after the first thinned portion forming step.

FIG. 18 is a diagram illustrating a first chamfering step.

FIG. 19 is a diagram showing the chips having been chamfered in the first chamfering step.

FIG. 20 is a diagram illustrating a second protective film forming step.

FIG. 21 is a diagram illustrating a second thinned portion forming step.

FIG. 22 is a diagram illustrating a second chamfering step.

FIG. 23 is a diagram showing the chips having been chamfered in the second chamfering step.

FIG. 24 is a flowchart illustrating a method for manufacturing chips according to a sixth embodiment.

### DESCRIPTION OF EMBODIMENTS

Hereinafter, with reference to the accompanying drawings, embodiments of the method for manufacturing chips according to the present disclosure will be described. Methods for manufacturing chips in the embodiments described below include a method for producing a plurality of chips by dividing a substrate along predetermined dicing lines. Operations to be performed in each step in the method for manufacturing chips according to the present disclosure are controlled by a control unit provided in each device that is configured to perform processes in the step. Therefore, unless otherwise stated in the description of the step, the control unit of the relevant device shall be regarded as the controlling entity. In the embodiments below, solely a control unit 24 in a laser processing apparatus 20 is illustrated; however, other devices used in the manufacturing method of the present disclosure, such as a protective film forming apparatus 10, a plasma processing apparatus 30, etc., are also provided with respective control units.

Optionally, an integrated processing system (cluster system) including a plurality of apparatuses such as the protective film forming apparatus 10, the laser processing apparatus 20, and the plasma processing apparatus 30 may be built, and the manufacturing method of the present disclosure may be implemented under the control of a system control unit that may collectively control the processing system.

### First Embodiment

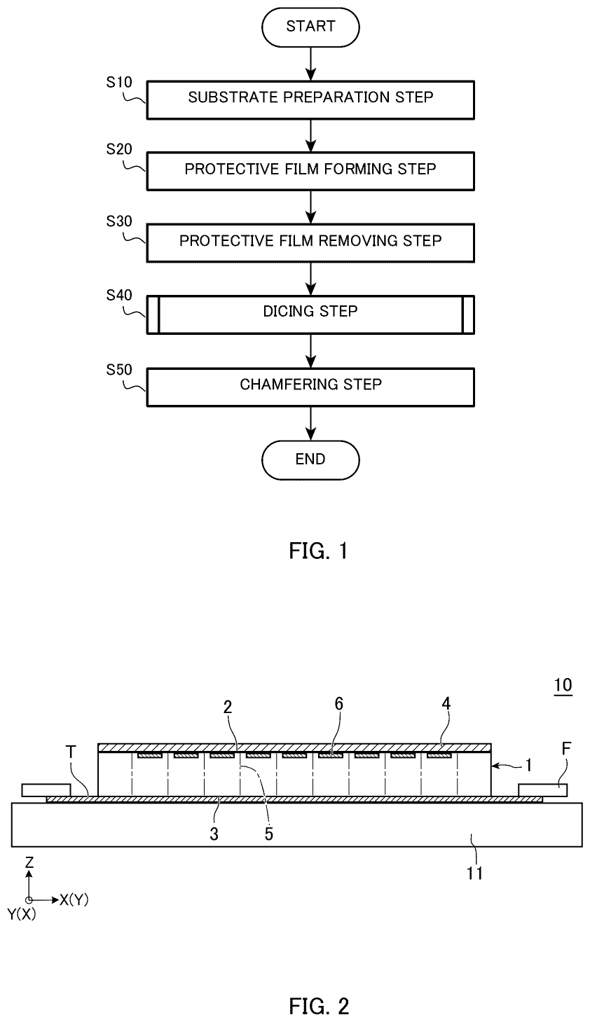

FIG. 1 is a flowchart illustrating a method for manufacturing chips according to a first embodiment. As shown in FIG. 1, a method for manufacturing chips according to the present embodiment includes a substrate preparation step, a protective film forming step, a protective film removing step, a dicing step, and a chamfering step. FIGS. 2-7 are diagrams to illustrate steps in the present embodiment, and FIG. 8 is a flowchart to illustrate details of the dicing step. Details of the steps will be described below.

First, in the substrate preparation step, a substrate 1 is prepared (step S10). The substrate 1 may be, for example, a disk-shaped wafer, and includes a first surface 2 and a second surface 3 facing opposite to the first surface 2. Two directions intersecting orthogonally with each other on a plane parallel to the first surface 2 are defined as an X direction and a Y direction. A direction intersecting orthogonally with the first surface 2 is defined as a Z direction. The Z direction may be referred to as a vertical direction, depth direction, or thickness direction, but these terms are merely examples that may be used for convenience of explanation. As shown in FIG. 4, the substrate 1 has a plurality of device regions sectioned by streets along predetermined dicing lines 5 extending in the X and Y directions in a form of grid, and devices 6 are formed in the respective device regions on the first surface 2 side.

For example, the substrate 1 may be manufactured by grinding a disk-shaped silicon wafer to a predetermined thickness, polishing the first surface 2 into a mirror finish, and forming the devices 6 on the first surface 2. However, the material or type of the substrate 1 is not necessarily limited to this example. Moreover, the substrate 1 may not necessarily be limited to the disk-shaped wafer but may be a rectangular package substrate or a polygonal substrate other than rectangular. Furthermore, the type of the devices 6 is not necessarily limited, but various devices such as semiconductor devices, optical devices, or other devices are applicable.

Although the substrate preparation step is included as a first step in the embodiments of the present disclosure including the present embodiment, the manufacturing method of the present disclosure may start from the next step (i.e., the protective film forming step in the present embodiment) without providing the substrate preparation step as an independent process. In other words, the substrate preparation step may include a manufacturing process to manufacture the substrate 1 having the devices 6 or may involve obtaining a pre-manufactured substrate 1 without including the manufacturing process. For example, when a first manufacturer (maker) manufactures the substrate 1 having the devices 6, and a second manufacturer (maker) different from the first manufacturer dices the substrate 1 to manufacture chips, the manufacturing method of the present disclosure may be applied solely to the manufacturing process carried out by the second manufacturer.

FIG. 2 is a diagram illustrating the protective film forming step. Once the substrate 1 is prepared, the protective film forming step is performed (step S20). The protective film forming step may be performed, for example, by the protective film forming apparatus 10.

In the protective film forming step, the protective film forming apparatus 10 forms a protective film 4 on the first surface 2 of the substrate 1. More specifically, the protective film forming apparatus 10 suctions the second surface 3 of the substrate 1, which forms a part of a frame unit carried into the protective film forming apparatus 10, against a table 11 through a tape T to hold the substrate 1. The frame unit is composed of a ring-shaped frame F and the substrate 1 attached to the tape T, which closes an opening formed in the frame F. The tape T may be a tape that includes an adhesive layer and a base layer, or may be a tape formed of a base layer of thermoplastic resin that generates an adhesive force in response to temperature change (a tape without an adhesive layer). The protective film forming apparatus 10, while suctioning the second surface 3 to hold the substrate 1 against the table 11, forms the protective film 4 on the first surface 2, which is on the opposite side of the second surface 3.

The protective film 4 is a film that protects the substrate 1 from plasma-etching and may be any material as long as the film is resistant to plasma-etching. The protective film 4 may be, for example, a negative-typed photoresist designed to withstand plasma-etching under predetermined conditions, which are described later. In this case, for example, a spin coater and an exposure apparatus may be used as the protective film forming apparatus 10. The spin coater is a device that applies liquid onto a flat surface using a rotational centrifugal force and supplies a liquid photoresist onto the first surface 2 of the substrate 1 from an unshown nozzle while rotating the table 11. The negative-typed photoresist, uniformly applied on the first surface 2 by the spin coater, is exposed to light using the exposure apparatus to form the protective film 4. Optionally, the protective film 4 may be formed by using a spray coater as the protective film forming apparatus 10, which may spray and apply the liquid resin onto the first surface 2. For another example, the protective film 4 may be formed by placing a preformed sheet-formed resin film or the like onto the first surface 2. Preferably, the protective film 4 is formed of a water-soluble material. When the protective film 4 is a water-soluble resin film, for example, the film may be removed by washing or peeling using water without chemicals, thereby simplifying equipment for cleaning or peeling.

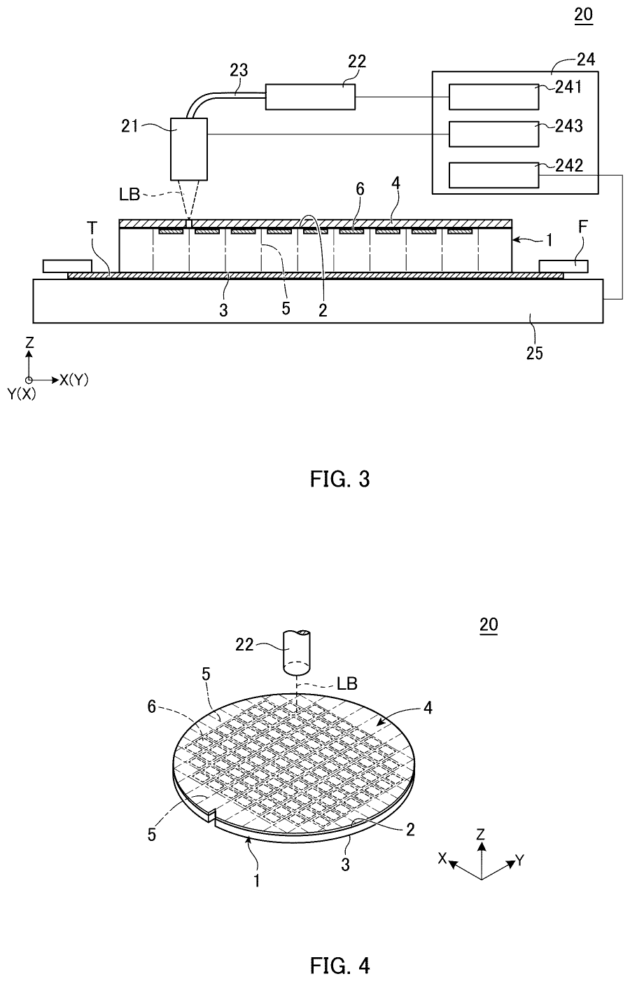

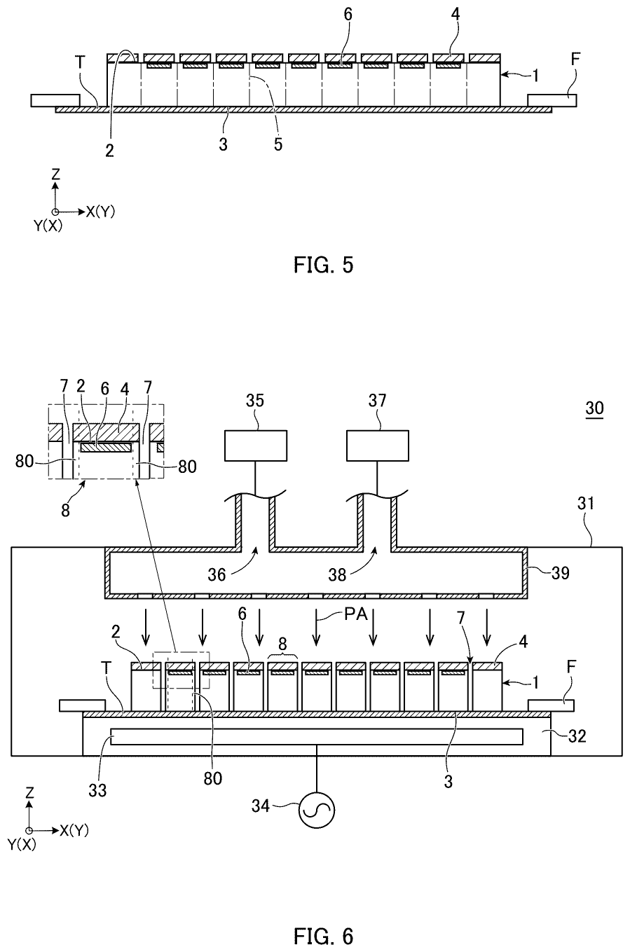

FIGS. 3 and 4 are diagrams illustrating the protective film removing step. FIG. 5 is a diagram showing the substrate 1 after the protective film removing step. After the protective film 4 is formed on the first surface 2 of the substrate 1, the protective film removing step is performed (step S30). The protective film removing step may be performed, for example, by the laser processing apparatus 20.

As shown in FIG. 3, the laser processing apparatus 20 includes a laser processing head 21, a laser oscillator 22, a transmission fiber 23, the control unit 24, and a table 25.

The laser oscillator 22 generates a laser beam (laser light) LB. The laser oscillator 22 may be, for example, a solid-state laser source, a gas laser source, a fiber laser source, or a semiconductor laser source. The laser oscillator 22 is connected to an input end of the transmission fiber 23, and the laser processing head 21 is connected to an output end of the transmission fiber 23. The laser beam LB emitted from the laser oscillator 22 is transmitted to the laser processing head 21 via the transmission fiber 23.

The control unit 24 includes a laser oscillator control unit 241, a table position control unit 242, and a laser processing head position control unit 243. The laser oscillator control unit 241 controls output intensity of the laser beam LB from the laser oscillator 22 and timing operations such as start and stop of the output. The table position control unit 242 controls a position of the table 25. For example, the table 25 may be moved in the X direction or the Y direction, or rotated about an axis that extends through a center of the table 25 in parallel to the Z direction. The laser processing head position control unit 243 moves a position of the laser processing head 21 in, for example, the Z direction (vertical direction), the X direction, or the Y direction. The table position control unit 242 and the laser processing head position control unit 243 cooperate to locate a focal point of the laser beam LB emitted from the laser processing head 21 at a desired position on the substrate 1 or the protective film 4 placed on the table 25.

In the protective film removing step, the laser processing apparatus 20 removes the protective film 4 formed on the substrate 1 along the predetermined dicing lines 5. More specifically, as shown in FIG. 3, the laser processing apparatus 20 suctions the second surface 3 of the substrate 1 to hold the substrate 1 against the table 25 via the tape T and focuses the laser processing head 21 so that the focal point is located on the protective film 4. Thereafter, the laser processing apparatus 20 emits the laser beam LB from the laser processing head 21 and focuses the laser beam LB onto the protective film 4. Further, as shown in FIG. 4, the laser processing head 21 is moved relatively to the substrate 1 so that the focal point of the laser beam LB moves along the predetermined dicing lines 5. Accordingly, as shown in FIG. 5, the protective film 4 is removed along the predetermined dicing lines 5 that were irradiated with the laser beam LB.

As such, the protective film removing step does not remove the entire protective film 4 but removes the protective film 4 only in portions along the predetermined dicing lines 5, leaving the other regions of the protective film 4 unremoved. The regions where the protective film 4 remains include areas where the devices 6 are formed in the device regions. In other words, at the time when the protective film removing step is completed, the devices 6 are individually covered with the protective film 4.

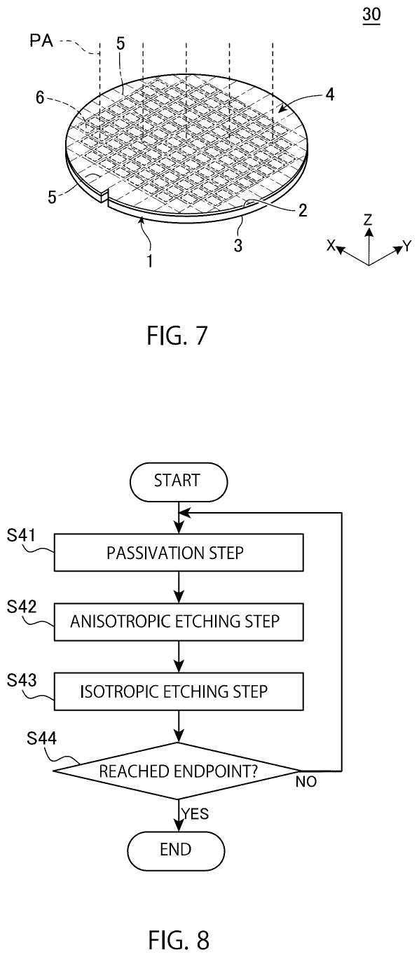

FIGS. 6 and 7 are diagrams illustrating the dicing step. FIG. 8 is a flowchart illustrating a Bosch process executed in the dicing step. After the protective film 4 is removed along the predetermined dicing lines 5 (see FIG. 5), the dicing step is performed (step S40). The dicing step may be performed, for example, by the plasma processing apparatus 30.

In the dicing step, the plasma processing apparatus 30 divides the substrate 1 along the predetermined dicing lines 5 by performing plasma-etching under a first condition from the first surface 2 side using the protective film 4 as a mask. More specifically, first, the frame unit carried into a chamber 31 of the plasma processing apparatus 30 is placed on a table 32 in the chamber 31 such that the tape T side (the second surface 3 side) faces the table 32. The substrate 1 placed on the table 32 is in a state where the protective film 4 is exposed upward inside the chamber 31.

Thereafter, the plasma processing apparatus 30 supplies a predetermined type of gas into the chamber 31 from a gas head 39 and causes plasma to be discharged between the gas head 39 and an electrode 33, which is located inside the table 32, by power from a high-frequency power supply 34. Accordingly, the gas in the chamber 31 is converted into plasma, and plasma-etching is performed in the thickness direction on the substrate 1 from the first surface 2 side by plasma PA. As plasma-etching is performed, portions of the first surface 2 that are exposed along the predetermined dicing lines 5 (i.e., streets between the adjacent devices 6) are etched to form grooves 7 in the substrate 1. In the dicing step, plasma-etching is continued until the grooves 7 reach the second surface 3, whereby the substrate 1 is divided along the predetermined dicing lines 5 and a plurality of chips 8 are formed.

In the dicing step, it is preferable that the plasma processing apparatus 30 performs a so-called Bosch process as plasma-etching under the first condition. The Bosch process is a type of reactive ion etching (RIE) for etching a workpiece (e.g., silicon) with a high aspect ratio, and is a process that repeatedly alternates a passivation step and an etching step at relatively short intervals. In the etching step of the Bosch process, anisotropic etching and isotropic etching are alternated through power control. Therefore, as shown in FIG. 8, the Bosch process includes the passivation step (step S41), the anisotropic etching step (step S42), and the isotropic etching step (step S43).

In the passivation step of step S41, the plasma processing apparatus 30 supplies C₄F₈ gas from a gas source 35 to the gas head 39 via a supply port 36, and generates C₄F₈ plasma in the chamber 31 by plasma discharge between the gas head 39 and an electrode 33. A fluorine-based polymer generated as a result of the plasma generation deposits in the grooves 7, and thereby the plasma processing apparatus 30 forms a protective film, which is a different type of protective film from the previously formed protective film 4, on surfaces of the grooves 7 (bottom and sidewalls of each groove 7).

In the etching step following the passivation step, the plasma processing apparatus 30 supplies SF₆ gas from a gas source 37 to the gas head 39 via a supply port 38, and generates SF₆ plasma in the chamber 31 by plasma discharge between the gas head 39 and the electrode 33. More specifically, the plasma processing apparatus 30 controls high-frequency power supplied from the high-frequency power supply 34 to the electrode 33 to a first power level, which is higher than the high-frequency power used in the passivation step, at the beginning of the etching step. Accordingly, charged ions in the SF₆ plasma are intensely attracted to the electrode 33 by a large electric field generated by the first power and are accelerated in the depth direction of the grooves 7. As a result, the accelerated ions collide with the bottom of each groove 7, removing the protective film formed on the bottom, and the combination of the ion collision and the reaction of fluorine radicals in the SF₆ plasma with silicon causes anisotropic etching of the silicon in the depth direction of the grooves 7 (step S42).

Thereafter, the plasma processing apparatus 30 controls the high-frequency power supplied to the electrode 33 to a second power level, which is lower than the first power level. Accordingly, by suppressing the power, the etching rate in the widthwise direction is adjusted, and with the adjusted etching rate, isotropic etching is performed using the fluorine radicals (step S43).

When the isotropic etching is performed for a predetermined length of period, an endpoint is determined (step S44). In the dicing step of the present embodiment, it is determined that the etching reached an endpoint (YES in step S44) when the bottoms of the grooves 7 reaching the second surface 3 are detected (i.e., the grooves 7 penetrate from the first surface 2 to the second surface 3), and the Bosch process ends thereat. If it is determined that the etching has not reached the endpoint (NO in step S44), the cycle of the passivation step (step S41) and the etching steps (steps S42 and S43) is repeated.

As such, the etching steps in the Bosch process include the isotropic etching following the anisotropic etching. Therefore, in the dicing step, it is preferable to repeat the passivation step and the etching steps (the anisotropic step and the isotropic etching step) in a relatively short time to prevent excessive progress of isotropic etching. This allows etching to proceed in the depth direction while protecting sidewalls of the grooves 7 with the protective film, thereby enabling high-aspect-ratio etching.

As shown in FIG. 6, each of the chips 8 divided in the dicing step has a peripheral region 80 adjacent to the grooves 7. The peripheral region 80 of each chip 8 may be, for example, a region outside the region where the device 6 is provided.

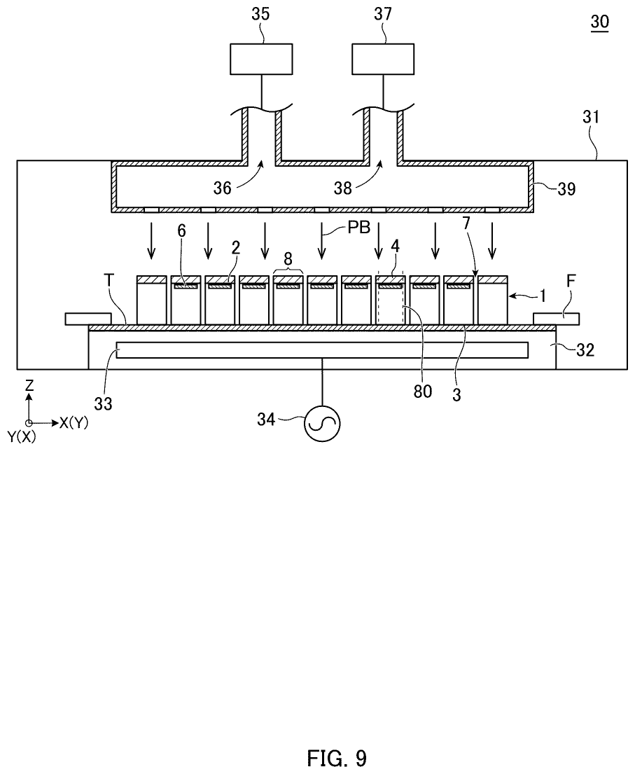

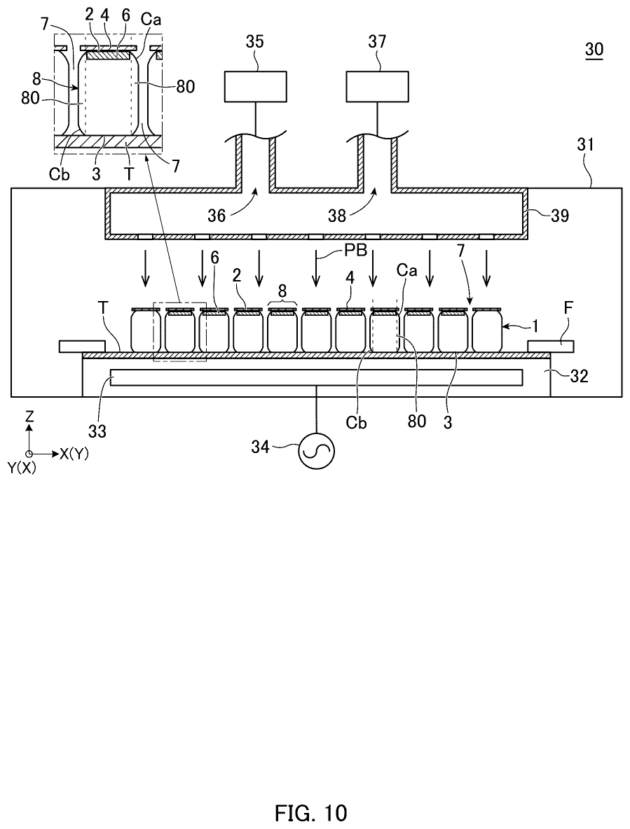

FIGS. 9 and 10 are diagrams illustrating the chamfering step. After the substrate 1 is divided into the plurality of chips 8 in the dicing step, the chamfering step is performed (step S50). The chamfering step may likewise be performed, for example, by the plasma processing apparatus 30, as is the dicing step.

In the chamfering step, the plasma processing apparatus 30 chamfers edge portions (outer edges) of the peripheral regions 80 of the chips 8 using plasma-etching under a second condition, which is different from the first condition in the dicing step. More specifically, as shown in FIG. 9, the plasma processing apparatus 30 supplies a predetermined type of gas into the chamber 31 from the gas head 39 and causes plasma to be discharged between the gas head 39 and an electrode 33 using the power from the high-frequency power supply 34. Accordingly, the gas in the chamber 31 is converted into plasma, and plasma-etching is performed on the chips 8 from the first surface 2 side by plasma PB.

As such, in a state where the grooves 7 having the high aspect ratio are formed by the dividing step, when plasma-etching under the second condition is further performed, as shown in FIG. 10, the edge portions of the chips 8 are particularly chamfered on the first surface 2 side of the substrate 1, which is most exposed to the plasma PB, and chamfered portions Ca are formed on the first surface 2 side of the peripheral regions 80 of the chips 8. Furthermore, due to the plasma gas that enters and remains within the grooves 7, chamfering of the edge portions on the second surface 3 side of the chips 8 is promoted, and chamfered portions Cb are formed on the second surface 3 side of the peripheral regions 80 of the chips 8. Accordingly, in the chamfering step, the edge portions on both surfaces of the chips 8 are chamfered.

It is preferable that the plasma-etching under the second condition is performed without excessively widening the grooves 7 formed in the dividing step in the widthwise direction, and particularly the edge portions of the chips 8 on the first surface 2 side are chamfered sufficiently. Therefore, the plasma-etching under the second condition is preferably anisotropic etching, in which etching progress in the widthwise direction of the grooves 7 is suppressed.

The gas to be used in the plasma-etching under the second conditions is not particularly limited but may be, for example, SF₆ gas or Ar gas. Moreover, in order to sufficiently chamfer the edge portions of the chips 8, plasma-etching under the second conditions is preferably performed for a time period substantially longer than a single etching step repeated in the dicing step. Specifically, for example, a cycle of the Bosch process in the dicing step (from step S41 to step S43 as shown in FIG. 8) may be approximately several seconds, and a unit duration of anisotropic etching (step S42) within the cycle may be approximately several seconds. In contrast, plasma-etching in the chamfering step may be continuously performed for one minute or more (e.g., 1.5 minutes). As described above, while in both isotropic and anisotropic etching in the Bosch process, plasma gas is supplied to the wafer by supplying predetermined high-frequency power to the lower electrode (the electrode 33) and the upper electrode (the gas head 39), specifically in the anisotropic etching, the high-frequency power to be supplied to the lower electrode (the electrode 33) is set to be higher than that in isotropic etching so that ions in the plasma are intensely attracted to the lower electrode (the electrode 33), thereby realizing vertical processing. The same applies to anisotropic etching in the chamfering step.

As such, the chamfering step of the present embodiment actively utilizes the effect of grinding the edges on the entry side of grooves 7 that are most exposed to plasma and the effect of grinding the edges on the bottom side of grooves 7 due to the retention of the plasma gas entering the grooves 7, which are considered to be rather undesirable in normal etching, in order to chamfer at least one of, and preferably both, the first surface 2 side and the second surface 3 side in the peripheral regions 80 of the chips 8. In particular, by performing anisotropic etching in the chamfering step for a period significantly longer than the cycle of the Bosch process, the chips 8 may be chamfered without significantly widening the entire width of each groove 7.

As described above, in the method for manufacturing chips according to the present embodiment, the edge portions of the peripheral regions 80 of the plurality of chips 8, which are formed by dividing the substrate 1, may be chamfered. By eliminating the corners on the outer surface of the chips 8 through chamfering, the strength (durability) of the chips 8 may be improved, and collisions between adjacent chips 8 at the edge portions and the resulting excessive load may be avoided. As a result, damage originating at the edge portions of each chip 8 may be suppressed.

In the chamfering step of the present embodiment, the plurality of chips 8 formed by dividing the substrate 1 may be chamfered at once collectively. This allows for more efficient chamfering compared to sequentially chamfering individual chips 8 one by one. Further, by performing both dividing of the substrate 1 into the plurality of chips 8 and chamfering using plasma-etching, the dicing step and the chamfering step may be performed successively in the same apparatus. This may also improve the operational efficiency. Therefore, according to the method for manufacturing chips of the present embodiment, the chips may be chamfered efficiently and may be manufactured efficiently.

### Second Embodiment

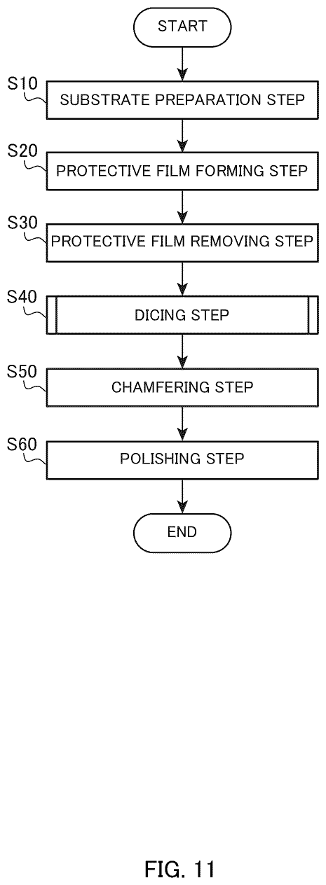

FIG. 11 is a flowchart illustrating a method for manufacturing chips according to a second embodiment. The method for manufacturing chips shown in FIG. 11 is similar to the first embodiment at a part from the substrate preparation step (step S10) through the chamfering step (step S50), but differs from the first embodiment in that a polishing step (step S60) is further performed after the chamfering step (step S50). The polishing step may likewise be performed, for example, by the plasma processing apparatus 30, as is in the dicing step and the chamfering step.

In the polishing step, the plasma processing apparatus 30 polishes side surfaces of the chips 8, which are formed by dividing the substrate 1, in isotropic etching. More specifically, the plasma processing apparatus 30 supplies a predetermined gas from the gas head 39 into the chamber 31 and generates plasma discharge between the gas head 39 and the electrode 33 using the power from the high-frequency power supply 34. This converts the gas in the chamber 31 into plasma, and isotropic etching is performed on the chips 8 from the first surface 2 side. As such, with the plurality of chips 8 being divided by the grooves 7, more isotropic etching is performed to etch and polish the sidewalls of the grooves 7, which are side surfaces of the chips 8.

It is preferable that the relation between the isotropic etching in the polishing step and the anisotropic etching in the chamfering step satisfies at least one of the following conditions: a condition where the time for performing the isotropic etching in the polishing step is shorter than the time for performing the anisotropic etching in the chamfering step; and a condition where the high-frequency power supplied to the upper electrode and to the lower electrode is lower in isotropic etching than in anisotropic etching.

It should be noted that isotropic etching performed in the polishing step may be any process as long as the side surfaces of the chips 8 are polished. Accordingly, the processing method to be applied in the polishing step is not necessarily limited to plasma-etching; however, plasma-etching is preferred because it enables the polishing to be performed in the same apparatus as in the dividing step and the chamfering step, thereby improving work efficiency. Moreover, the gas to be used in the polishing step is not particularly limited, but may be the same as that used in the dicing step, such as SF₆ gas, or a different gas may also be used.

As described above, in the method for manufacturing chips according to the present embodiment, after the chamfering step, the polishing step (e.g., isotropic plasma-etching) is additionally performed, and thereby, the side surfaces of the plurality of chips 8 formed by dividing the substrate 1 may be polished collectively. Accordingly, the side surfaces may be polished more efficiently than when polishing the side surfaces of the individual chips 8 one by one serially. Further, by dividing and chamfering the chips 8 in plasma-etching and by polishing the chips 8 also with plasma-etching, the dicing step, the chamfering step, and the polishing step may be successively performed in the same apparatus. This may also improve the operational efficiency. Therefore, according to the method for manufacturing chips of the present embodiment, small-sized wafers may be produced more efficiently.

It should be noted that the third through sixth embodiments described below may also include the polishing step for polishing the side surfaces of the chips 8, similarly to the present embodiment.

### Third Embodiment

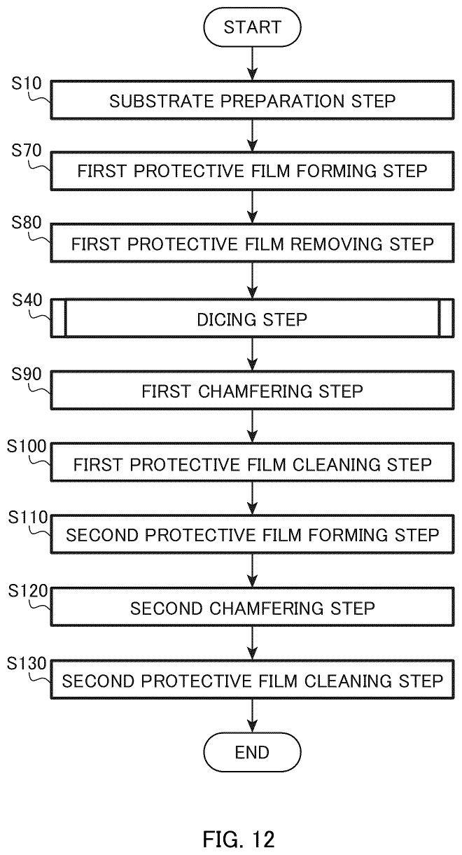

FIG. 12 is a flowchart illustrating a method for manufacturing chips according to a third embodiment. The method for manufacturing chips shown in FIG. 12 differs from the method of the first embodiment in that the chamfering step is performed individually on each of the two surfaces of the chips 8 to reliably chamfer the edge portions on the both sides.

In the present embodiment, in order to distinguish a process on the first surface 2 side and a process on the second surface 3 side of the substrate 1 (the chips 8), the protective film formed on the first surface 2 side (a protective film corresponding to the protective film 4 in the first embodiment) is referred to as a first protective film. Moreover, a step to form the first protective film is referred to as a first protective film forming step (step S70), and a step to remove the first protective film along the predetermined dicing lines 5 is referred to as a first protective film removing step (step S80).

The first protective film forming step is similar to the protective film forming step (step S20) of the first embodiment, and may be performed, for example, by the protective film forming apparatus 10 as shown in FIG. 2. The first protective film removing step is similar to the protective film removing step (step S30) of the first embodiment, and may be performed, for example, by the laser processing apparatus 20 as shown in FIGS. 3 and 4. Further, a dicing step (step S40) is similar to the dicing step (step S40) of the first embodiment, and may be performed, for example, by the plasma processing apparatus 30 as shown in FIG. 6. In other words, in a part from the substrate preparation step (step S10) through the division step (step S40) in this embodiment, the processing contents are the same as those of the corresponding steps in the first embodiment, except that the names of the first protective film formation step and the first protective film removal step are different from those of the protective film formation step and the protective film removal step in the first embodiment.

In the method for manufacturing chips of the present embodiment, after the dicing step, a first chamfering step is performed by plasma-etching on the chips 8 from the first surface 2 side (step S90). This first chamfering step is similar to the chamfering step in the first embodiment (see FIGS. 9 and 10). By performing the first chamfering step, the edge portions on the first surface 2 side of the peripheral regions 80 of the chips 8 are chamfered, as shown in FIG. 10 (chamfered portions Ca are formed). Meanwhile, the edge portions on the second surface 3 side of the peripheral regions 80 of the chips 8 are chamfered in a second chamfering step described later; therefore, unlike in FIG. 10, chamfering of the second surface 3 side of the chips 8 is not necessarily be promoted in the first chamfering step. In other words, in the first chamfering step, plasma-ctching may be performed under conditions that focus on chamfering the first surface 2 side of the chips 8, which is the side most exposed to the plasma.

After the first chamfering step, a first protective film cleaning step is performed (step S100). In the first protective film cleaning step, a spinner cleaning apparatus (not shown) cleans and removes the first protective film remaining on the first surface 2 of the substrate 1 (the chips 8).

After the first protective film is removed, a second protective film forming step is performed (step S110). The second protective film forming step may be performed, for example, by the protective film forming apparatus 10 in the same manner as the first protective film forming step. In the second protective film forming step, first, a new frame unit is composed by attaching a tape T to the first surface 2 side of the substrate 1 (the divided chips 8), and the frame unit is carried to the protective film forming apparatus 10. Thereafter, the protective film forming apparatus 10 operates in the same manner as in the first protective film forming step, except that the first surface 2 of the substrate 1 (the divided chips 8) is suctioned via the tape T to be held against the table 11, and forms a second protective film on the second surface 3 of each chip 8.

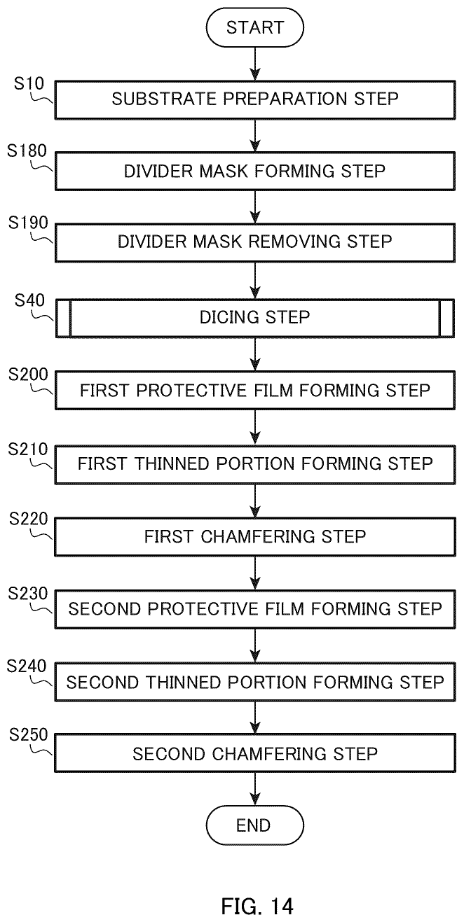

The step to form the second protective film on the second surface 3 of each chip 8 may be performed in the same manner as a second protective film forming step in a fifth embodiment (step S230 in FIG. 14, and FIG. 20), which will be described further below. More specifically, by performing the second protective film forming step in the present embodiment, the second protective film, which is similar to a second protective film 42 shown in FIG. 20, is formed on the second surface 3 of each chip 8. Although FIG. 20 shows a first protective film 40 remaining on the first surface 2 side, in the present embodiment, the first protective film cleaning step is performed before the second protective film forming step. Therefore, the second protective film forming step is conducted in a state where the first protective film 40 is removed from the first surface 2 side, unlike as shown in FIG. 20.

The second protective film formed on the second surface 3 may be, for example, of the same type (material) as the first protective film formed on the first surface 2 in the earlier first protective film forming step. However, the second protective film may be any protective film as long as the protective film is resistant to plasma-etching in the second chamfering step described later, and is not limited to the same type (material) as the first protective film formed on the first surface 2. In other words, in the second protective film forming step, a second protective film of a type (material) different from the first protective film may be formed.

After the second protective film is formed on the second surface 3 of the substrate 1 (the divided chips 8), the second chamfering step, which is the chamfering step for the second time, is performed (step S120). The second chamfering step may likewise be performed, for example, by the plasma processing apparatus 30, as is the first chamfering step.

In the second chamfering step, first, the frame unit carried into the chamber 31 of the plasma processing apparatus 30 is placed on the table 32 in the chamber 31 such that the tape T side (the first surface 2 side) faces the table 32. In other words, the vertical positions of the first surface 2 and the second surface 3 of the substrate 1 in FIG. 9 are reversed, and with the second protective film formed on the second surface 3 side, the frame unit is held in the chamber 31. Thereafter, the predetermined gas, which is the same as the gas used in the first chamfering step, is supplied into the chamber 31 from the gas head 39, and plasma discharge is caused between the gas head 39 and the electrode 33 using the power from the high-frequency power supply 34. This converts the gas in the chamber 31 into plasma, and plasma-etching with the same plasma as the first chamfering step is applied on the chips 8 from the second surface 3 side. By performing the second chamfering step, the edge portions on the second surface 3 side of the peripheral regions 80 of the chips 8 that are most exposed to plasma are particularly chamfered. In other words, chamfered portions similar to the chamfered portions Cb shown in FIG. 10 are formed on the second surface 3 side of the chips 8.

As the edge portions on the second surface 3 side of the chips 8 are chamfered, and the second chamfering step is completed, a second protective film cleaning step is performed (step S130). The second protective film cleaning step may be performed, for example, by the spinner cleaning device (not shown) in the same manner as the first protective film cleaning step. The spinner cleaning device cleans and removes the second protective film formed on the second surface 3 of the substrate 1 (chips 8).

As described above, in the method for manufacturing chips according to the present embodiment, by performing the first chamfering step and the second chamfering step after the dicing step, the edge portions on the both sides (the first surface 2 and the second surface 3) of the peripheral regions 80 of the chips 8 are chamfered reliably, and the chips 8 in a high quality and highly durable that may not be damaged easily may be provided. Further, chamfering on the both surfaces of the chips 8 may be performed efficiently, and the chips 8 may be manufactured efficiently.

### Fourth Embodiment

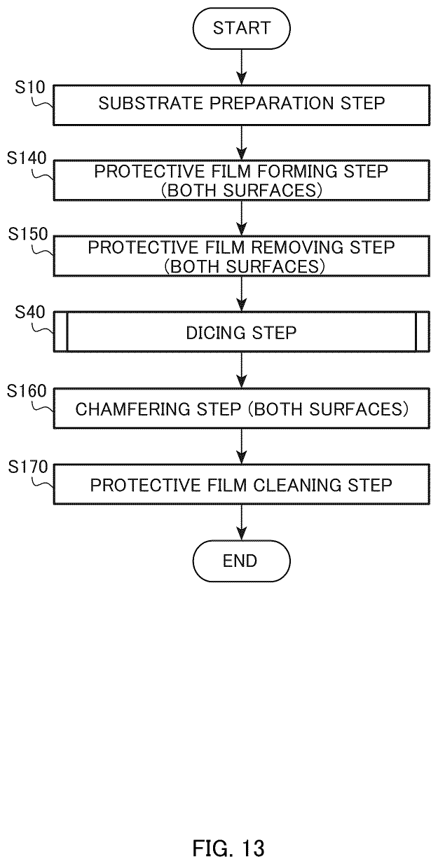

FIG. 13 is a flowchart illustrating a method for manufacturing chips according to a fourth embodiment. The method for manufacturing chips according to the present embodiment as shown in FIG. 13 involves, similarly to the method of the third embodiment, individually chamfering edge portions on the both sides of the peripheral regions 80 of the chips 8. However, the method for manufacturing chips of the present embodiment differs from that of the third embodiment in the following respects.

First, prior to the dicing step (step S40), a protective film forming step (step S140) is performed to form protective films on both surfaces (the first surface 2 and the second surface 3) of the undivided substrate 1. Next, a protective film removing step (step S150) is performed to remove the protective films along the predetermined dicing lines 5 from the both surfaces of the substrate 1. After the protective film removing step, unlike the substrate 1 shown in FIG. 5, the protective films, in which regions along the predetermined dicing lines 5 are removed, are formed on not only the first surface 2 side but also the second surface 3 side.

Next, a dicing step (step S40) is performed. In the dicing step, as shown in FIG. 6, the plasma processing apparatus 30 may be used to perform plasma-etching from the first surface 2 side of the substrate 1 in the thickness direction using plasma PA, thereby forming the grooves 7 along the predetermined dicing lines 5. Optionally, in the dicing step, the substrate 1 may be held in an orientation where the first surface 2 and second surface 3 are reversed from that in FIG. 6, and plasma-etching may be performed from the second surface 3 side to form the grooves 7 in the thickness direction. In the present embodiment, the protective film, in which the regions along the predetermined dicing lines 5 are removed, is also formed on the second surface 3; therefore, plasma-etching is performable from the second surface 3 side in the thickness direction to divide the substrate 1 into the chips 8.

After the dicing step, a chamfering step (step S160) is performed to chamfer the edge portions on the both sides of the chips 8. The chamfering step of the present embodiment is processed similarly to the first chamfering step (step S90) and second chamfering step (step S120) of the third embodiment. Thus, the edge portions on the both sides of chips 8 produced by dividing the substrate 1 are chamfered.

After the chamfering step, a protective film cleaning step (step S170) is performed to clean the protective films from the both surfaces of the chips 8. The protective film cleaning step of the present embodiment is performed using the spinner cleaning device (not shown), similarly to the first protective film cleaning step (step S100) and second protective film cleaning step (step S130) in the third embodiment.

The method for manufacturing chips according to the present embodiment performs processes generally similar to the third embodiment, except that the protective films (the first protective film and the second protective film) are formed on the both surfaces (the first surface 2 and the second surface 3) of the chips 8 before the dicing step. Therefore, similar to the method for manufacturing chips in the third embodiment, the edge portions on the both surfaces (the first surface 2 and the second surface 3) of the peripheral regions 80 of the chips 8 are reliably chamfered after the dicing step, and the chips 8 in a high quality and highly durable that may not be damaged easily may be provided. Further, chamfering on the both surfaces of the chips 8 may be performed efficiently, and the chips 8 may be manufactured efficiently.

### Fifth Embodiment

FIG. 14 is a flowchart illustrating a method for manufacturing chips according to a fifth embodiment. The method for manufacturing chips of the present embodiment performs, similarly to the method shown in the flowchart of FIG. 12 (the third embodiment), individual plasma-etching chamfering steps from the both surfaces (the first surface 2 side and the second surface 3 side) of the chips 8 after the substrate 1 is divided into the plurality of chips 8, thereby chamfering the edge portions on the both sides of the peripheral regions 80 of the chips 8. Unlike the first through fourth embodiments, the present embodiment includes a thinned portion forming step, in which the thickness of the protective film is varied within a plane of the chips 8 and the chips 8 are chamfered using the varied thicknesses of the protective film before the chamfering step.

Steps from the substrate preparation step (step S10) to the dicing step (step S40) in the present embodiment are the same in contents as those in the first embodiment; therefore, the configurations of the substrate 1 and the apparatuses used in the steps are described with reference to FIGS. 2 through 7. A divider mask in the present embodiment is a protective film having the same function as the protective film 4 formed on the first surface 2 of the substrate 1 and used as a mask in the dicing step (step S40) in the first embodiment, and the protective film 4 shown in FIGS. 2 through 7 may be regarded as the divider mask of the present embodiment.

After the substrate preparation step (step S10), a divider mask forming step is performed (step S180). The divider mask forming step is the same as the protective film forming step (step S20) of the first embodiment, and may be performed, for example, using the protective film forming apparatus 10 shown in FIG. 2. In the divider mask forming step, a divider mask is formed on the first surface 2 of the substrate 1 by the protective film forming apparatus 10. The divider mask is, similarly to the protective film 4 shown in FIGS. 2 through 7, a protective film that protects the substrate 1 from plasma-etching and may be made of any material 1 as long as the film is resistant to plasma-etching.

Next, a divider mask removing step is performed (step S190). The divider mask removing step is a process similar to the protective film removing step (step S30) in the first embodiment, and may be performed by, for example, the laser processing apparatus 20 shown in FIG. 3. The laser processing apparatus 20 moves the laser processing head 21 relatively to the substrate 1 so that the focal point of the laser beam LB travels along the predetermined dicing lines 5 on the divider mask (the protective film 4). Thus, the divider mask (the protective film 4) is removed along the predetermined dicing lines 5 that are irradiated with the laser beam LB.

Next, in the dicing step (step S40), plasma-etching is performed from the first surface 2 side using the divider mask (the protective film 4) as a mask, thereby dividing the substrate 1 into a plurality of chips 8 along the predetermined dicing lines 5. The dicing step may be performed, for example, using the plasma processing apparatus 30 shown in FIG. 6. In the dicing step, it is preferable that the plasma processing apparatus 30 performs the Bosch process (see FIG. 8) as the plasma-etching. The dicing step using the Bosch process has already been described in the first embodiment; therefore, detailed explanation is herein omitted.

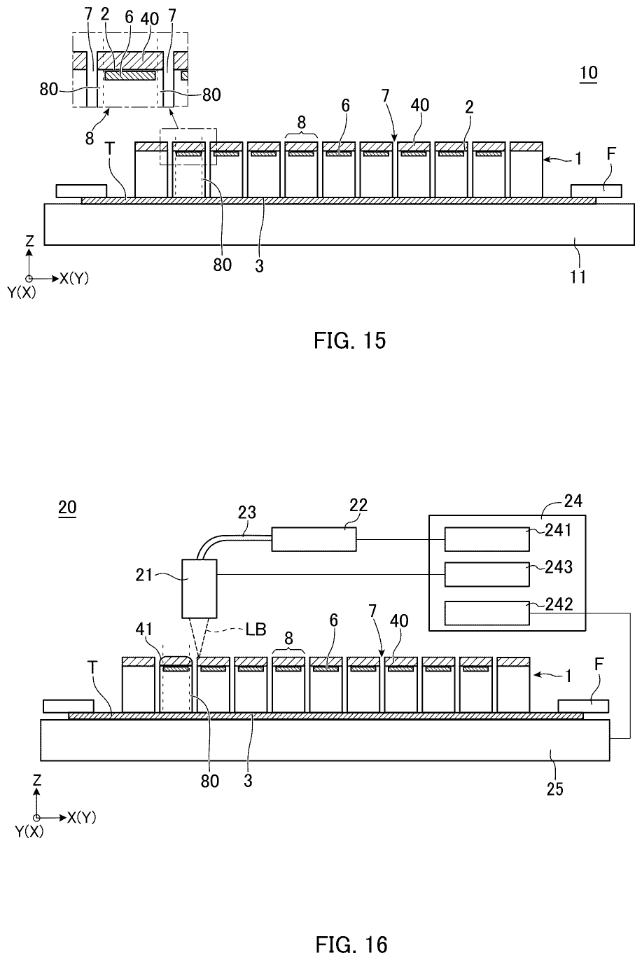

After the dicing step, the divider mask (the protective film 4) remaining on the first surface 2 of the chips 8 is removed by, for example, cleaning, and thereafter, a first protective film forming step is performed (step S200). Although the flowchart in FIG. 14 omits a step for cleaning the remaining divider mask, a separate divider mask cleaning step may be included between the dicing step and the first protective film forming step. FIG. 15 is a diagram illustrating an example of the first protective film forming step. The first protective film forming step may be performed, for example, using the protective film forming apparatus 10 to form the first protective film 40 on the first surfaces 2 of the divided chips 8.

Next, a first thinned portion forming step is performed (step S210). In the first thinned portion forming step, a first thinned portion 41 is formed in a predetermined region of the first protective film 40. More specifically, each chip 8 has the peripheral region 80 adjacent to the grooves 7 (see FIG. 15), and a first thinned portion 41 is formed in a peripheral region of the first protective film 40 overlapping the peripheral region 80. The region of the first thinned portion 41 is located outside the region where the device 6 is provided.

FIG. 16 is a diagram illustrating an example of the first thinned portion forming step. As shown in FIG. 16, the first thinned portion forming step may be performed, for example, using the laser processing apparatus 20. In the first thinned portion forming step, the second surface 3 of the substrate 1 (the divided chips 8) is suctioned to be held on the table 25 via the tape T, and the laser processing apparatus 20 is arranged such that the first protective film 40 faces the laser processing head 21. Prior to irradiation with the laser beam LB, the table position control unit 242 and the laser processing head position control unit 243 adjust the positions of the table 25 and the laser processing head 21 such that the focal point of the laser beam LB is located at an outer edge of the first protective film 40 (the outermost edge on the upper portion of the peripheral region 80 of a chip 8). Further, an output intensity of the laser beam LB, a focus height, a process-feeding speed, and a number of times of irradiation (number of passes) are set by the respective sections of the control unit 24, so that the removal amount (amount to cut) in the thickness direction (the depth direction) of the first protective film 40 equals a predetermined amount. Once the settings are completed, the laser oscillator control unit 241 starts outputting the laser beam LB.

The table position control unit 242 moves the table 25 at a predetermined feeding rate in a direction along one of the grooves 7 (e.g., a direction perpendicular to the plane of FIG. 16) while maintaining the output intensity of the laser beam LB, thereby moving the focal point of the laser beam LB in the horizontal direction. Accordingly, an outer edge of the first protective film 40 is removed to a predetermined depth, forming a notch.

Next, the respective sections of the control unit 24 change parameters, such as the output intensity of the laser beam LB, the focusing height, the process-feeding speed, and the number of times of irradiation (number of passes), to change the removal amount in the thickness direction of the first protective film 40. For example, the parameters may be changed to reduce the removal amount in the thickness direction of the first protective film 40. Next, the laser processing head position control unit 243 moves the position of the laser processing head 21, for example, rightward in FIG. 16, to move the focal point of the laser beam LB inward (toward the center) of the chip 8. Further, the table position control unit 242 moves the table 25 at a predetermined feeding rate in the direction along the groove 7 (e.g., perpendicular to the plane of FIG. 16), thereby shifting the focal point of the laser beam LB in the horizontal direction. Accordingly, a notch shallower (a notch with a smaller removal amount in the thickness direction of the first protective film 40) than the notch formed previously at the outer edge of the first protective film 40 is formed inside the previous notch.

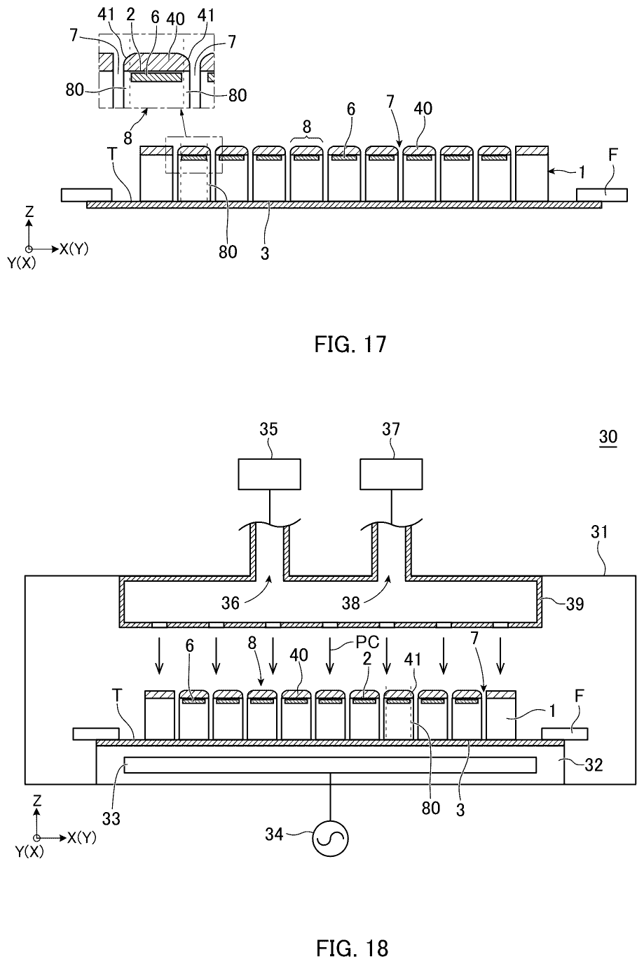

By repeating the above control, the first protective film 40 is processed from the outer side (the outer edge) toward the inner side in the peripheral region 80 of the chip 8, while gradually reducing the removal amount in the thickness direction. Each chip 8 in the present embodiment is substantially rectangular in a top view, and the process is performed to along all of the four sides of the peripheral region 80 of the chip 8. As such, in the first thinned portion forming step, the thickness of the remaining first protective film 40 is decreased from the inner side toward the outer edge of the chip 8, by varying the removal amount in the thickness direction of the first protective film 40 within the plane of the chip 8. As a result, as shown in FIG. 17, the first thinned portion 41 is formed in the peripheral region 80 (a region between the outer edge and a position at a predetermined distance from the outer edge) of the chip 8, in which the thickness of the film decreases from the inner side toward the outer edge of the chip 8.

In a case where the plurality of chips 8 are aligned in the process-feeding direction of the laser processing apparatus 20, the laser beam LB may successively irradiate the chips 8 aligned in the process-feeding direction during each feeding operation in the first thinned portion forming step, thereby efficiently forming the first thinned portions 41 on the plurality of chips 8.

It should be noted that the adjustment of the output intensity of the laser beam LB and the control of the focal point are not limited to the above examples. For example, the process-feeding operation to move the focal point of the laser beam LB in the horizontal direction may be implemented by moving the laser processing head 21 under the control of the laser processing head position control unit 243, rather than moving the table 25. For another example, the focal point of the laser beam LB may be controlled solely by the table position control unit 242.

In the foregoing example of the first thinned portion forming step, the first protective film 40 was processed stepwise from the outer side toward the inner side of the chip 8 while reducing the removal amount in the thickness direction of the first protective film 40. In contrast, optionally, the first protective film 40 may be processed stepwise from the inner side toward the outer side of the chip 8 while increasing the removal amount in the thickness direction of the first protective film 40.

Further, the laser processing apparatus 20 is not limited to the configuration using the fixed optical system as described above, but may employ a configuration using a scanning optical system. For example, the laser processing apparatus 20 may be equipped with a scanner having a galvanometer mirror (or polygon mirror) and an fθ lens in place of the laser processing head 21. In such a configuration, the traveling direction of the laser beam may be controlled by suitably adjusting an angle of the galvanometer mirror, and the laser beam may be focused at a desired position on the workpiece (the first protective film 40) with the fθ lens. In the case where the laser processing apparatus 20 is provided with the scanning optical system, the laser beam may be scanned without moving the position of the table 25 or the laser processing head 21.

FIG. 17 is a cross-sectional view of the substrate 1 (the chips 8) after the first thinned portion forming step. The first thinned portion 41 is formed in the peripheral region 80 of each of the plurality of chips 8 manufactured by dividing the substrate 1. As described above, the first thinned portion 41 is formed such that the film thickness decreases from the inner side toward the outer side of the chip 8. Moreover, the first thinned portion 41 is formed such that the amount of change in film thickness increases from the inside toward the outside of the chip 8. Meanwhile, the peripheral region 80 of the chip 8 lies outside the area where the device 6 is formed; therefore, the area of the first surface 2 of the chip 8 in which the device 6 is provided maintains the predetermined film thickness of the first protective film 40 without being thinned.

The method of forming the first thinned portion 41 in the first thinned portion forming step is not limited to the above-described laser processing. For example, the first thinned portion 41 may be formed by cutting or ion-beam processing. For another example, the first thinned portion 41 may be formed by applying plasma-etching such as O₂ ashing locally.

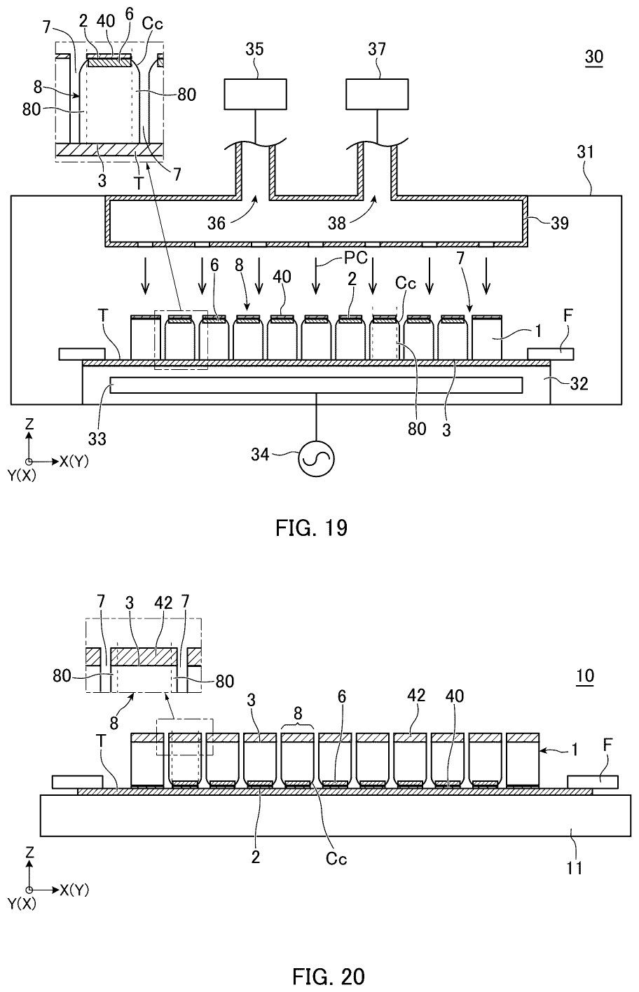

Next, a first chamfering step is performed (step S220). In the first chamfering step, plasma-etching is applied on the chips 8 using the first protective film 40 as a mask. FIGS. 18 and 19 are diagrams illustrating an example of the first chamfering step. The first chamfering step may be performed by, for example, the plasma processing apparatus 30.

As shown in FIG. 18, the frame unit carried into the chamber 31 of the plasma processing apparatus 30 is placed on the table 32 such that the tape T side (the second surface 3 side) faces the table 32, thereby exposing the first protective film 40 inward.

Thereafter, the plasma processing apparatus 30 supplies the predetermined type of gas into the chamber 31 from the gas head 39 and causes plasma to be discharged between the gas head 39 and the electrode 33, which is located inside the table 32, by power from the high-frequency power supply 34. This converts the gas in the chamber 31 into plasma. By plasma PC, the chips 8 are etched (plasma-etched) in the thickness direction (the depth direction) from the first surface 2 side. As the plasma-etching begins, the first protective film 40 formed on the first surface 2 of the chips 8 is etched first. As the etching proceeds, portions of the first surface 2 of the chips 8 are exposed sequentially, starting from the thinner portions of the first thinned portion 41.

While plasma-etching in the first chamfering step is being performed, not only the surface of the first protective film 40 but also the portions of the first surface 2 of the chips 8, which are exposed after removal of the first thinned portion 41, are etched. In each chip 8, the first thinned portion 41 is formed in the peripheral region 80 within the plane of the first surface 2. Further, the first thinned portion 41 is formed such that the thickness thereof decreases from the inner side toward the outer side of the chip 8. Therefore, the peripheral region 80 of the chip 8 is etched so as to trace the surface shape of the first thinned portion 41. As a result, when the first chamfering step is completed, the edge portion on the first surface 2 of the peripheral region 80 of the chip 8 is chamfered, and a chamfered portion Cc is formed, as shown in FIG. 19. In the region inside the peripheral region 80, the first protective film 40 remains, and the device 6 located inside the peripheral region 80 is protected from plasma-etching during the first chamfering step. When the first thinned portion 41 is completely removed and the chamfered portion Cc is formed, the plasma-etching of the first chamfering step is terminated.

After the first chamfering step, the second surfaces 3 of the chips 8 are chamfered in the same manner as on the first surfaces 2. First, after the first chamfering step is completed, the tape T is reattached from the second surface 3 side to the first surface 2 side of the chips 8, and a second protective film forming step (step S230) is performed. FIG. 20 is a diagram illustrating an example of the second protective film forming step. The second protective film forming step may be performed, for example, using the protective film forming apparatus 10. More specifically, as shown in FIG. 20, the substrate 1 (the chips 8) is reversed vertically and placed such that the first surface 2 is in contact with the table 11 via the tape T and the first protective film 40. Thereafter, a second protective film 42 is formed on the second surface 3 of each of the divided chips 8.

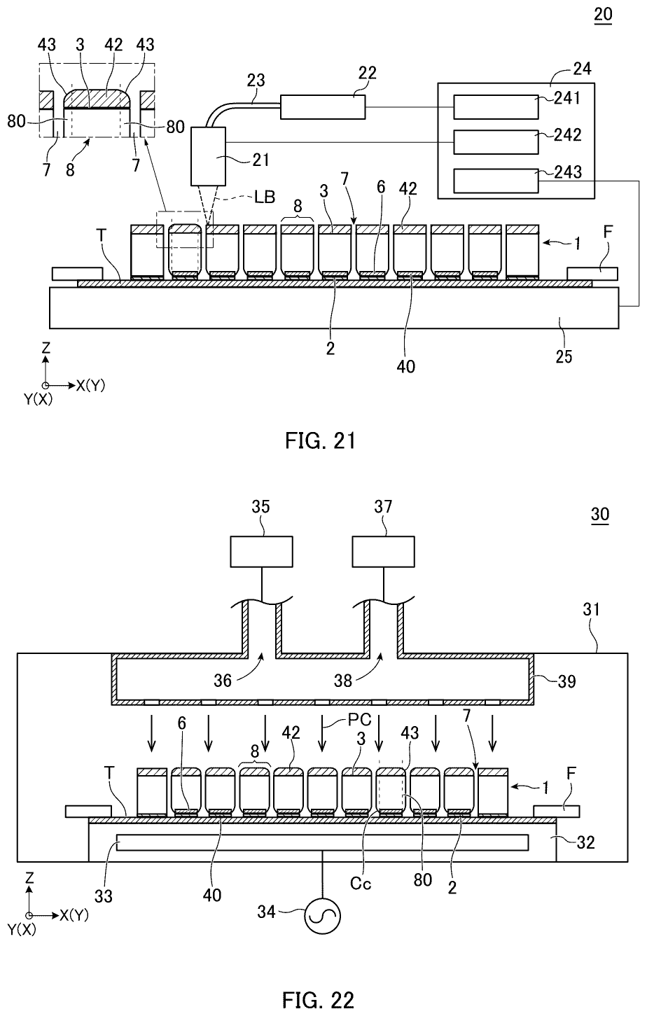

Next, a second thinned portion forming step is performed (step S240). In the second thinned portion forming step, a second thinned portion 43 is formed in a predetermined region of the second protective film 42. More specifically, the second thinned portions 43 are formed in peripheral regions of the second protective film 42 that overlap the peripheral regions 80 of the chips 8. FIG. 21 is a diagram illustrating an example of the second thinned portion forming step. The second thinned portion forming step may be performed using, for example, the laser processing apparatus 20. The second thinned portion forming step involves processing the second protective film 42 on the second surface 3 side while the substrate 1 (the chips 8) vertically inverted is held on the table 25 via the tape T and the first protective film 40. Aside from this inverted setting, the process content is the same as that of the previously described first thinned portion forming step (step S210), and detailed explanation is herein omitted.

In the second thinned portion forming step, the second protective film 42 is removed so that the thickness of the second protective film 42 after the second thinned portion forming step is decreased from the inner side toward the outer edge of the chip 8, by varying the removal amount in the thickness direction of the second protective film 42 within the plane of each chip 8. As a result, the second thinned portion 43 is formed in the peripheral region 80 (a region between the outer edge and a position at a predetermined distance from the outer edge) of the chip 8, in which the film thickness decreases from the inside toward the outside of the chip 8. The second thinned portion 43 is formed such that the amount of change in film thickness increases from the inside toward the outside of the chip 8.

The method of forming the second thinned portion 43 in the second thinned portion forming step is not limited to the above-described laser processing by the laser processing apparatus 20. As in the modified examples mentioned in the first thinned portion forming step, processing methods such as, for example, cutting or ion-beam processing may be applied in the second thinned portion forming step. For another example, the second thinned portion 43 may be formed by applying plasma etching such as O₂ ashing locally.

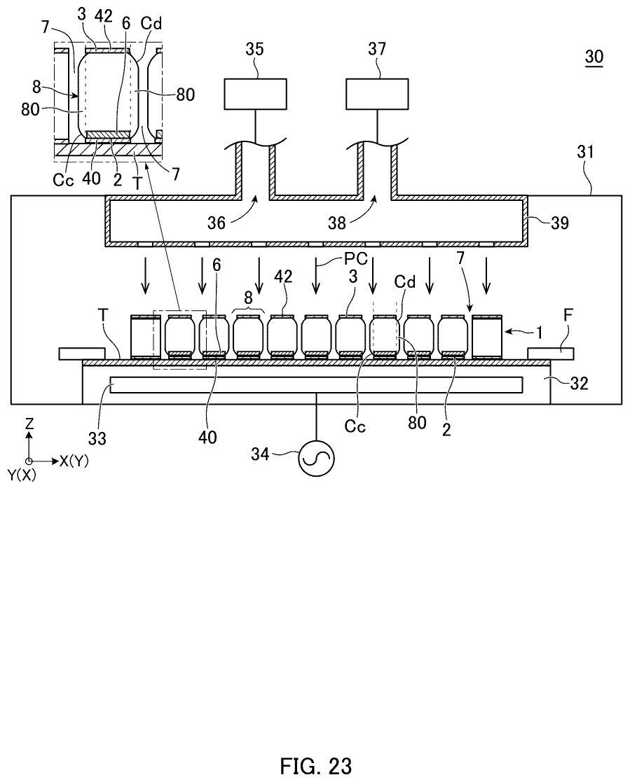

Next, a second chamfering step is performed (step S250). In the second chamfering step, plasma-etching is applied on the chips 8 using the second protective film 42 as a mask. FIGS. 22 and 23 are diagrams illustrating an example of the second chamfering step. The second chamfering step may be performed by, for example, the plasma processing apparatus 30. In the second chamfering step, etching is applied on the edge portions of the second surfaces 3 of the chips 8 while the substrate 1 (the chips 8) vertically inverted is held on the table 25 via the tape T and the first protective film 40. Aside from this inverted setting, the processing content is the same as that of the first chamfering step (step S220) described above, and a brief explanation is provided herein.

As shown in FIG. 22, the plasma processing apparatus 30 converts the gas in the chamber 31 into plasma and etches (plasma-etching) the chips 8 in the thickness direction (depth direction) from the first surface 2 side by plasma PC. First, the second protective film 42 formed on the second surfaces 3 of the chips 8 are etched, and as the etching proceeds, portions of the second surfaces 3 of the chips 8 are exposed sequentially, starting from the thinner portions of the second thinned portions 43.

While plasma-etching in the second chamfering step is being performed, not only the surface of the second protective film 42 but also the portions of the second surfaces 3 of the chips 8, which are exposed after removal of the second thinned portions 43, are etched. In each chip 8, the second thinned portion 43 is formed in the peripheral region 80 within the plane of the second surface 3. Further, the second thinned portion 43 is formed such that the thickness thereof decreases from the inner side toward the outer side of the chip 8. Therefore, the peripheral region 80 of the chip 8 is etched so as to trace the surface shape of the second thinned portion 43. As a result, when the second chamfering step is completed, the edge portion on the second surface 3 of the peripheral region 80 of the chip 8 is chamfered, and a chamfered portion Cd is formed, as shown in FIG. 23. When the second thinned portion 43 is completely removed and the chamfered portion Cd is formed, the plasma-etching of the second chamfering step is terminated.

Through the series of steps as described above, the chips 8 having the chamfered shapes (the chamfered portion Cc and the chamfered portion Cd) at the edge portions on the both surfaces of the peripheral region 80 are manufactured. Optionally, after the second chamfering step, a step for removing (e.g., peeling or cleaning) the first protective film 40 and the second protective film 42 remaining on the surfaces of the chips 8 may be performed.

As described above, the method for manufacturing chips according to the present embodiment forms the protective films (the first protective film 40 and the second protective film 42) on the surfaces (the first surface 2 and the second surface 3) of the plurality of chips 8 that are formed by dividing the substrate 1, and further forms the thinned portions (the first thinned portion 41 and the second thinned portion 43) by partially thinning the protective films. Further, by applying plasma-etching using the protective film as a mask and tracing the surface shape of the thinned portions (varying the removal amount in the thickness direction within the plane), the peripheral regions 80 of the chips 8 are chamfered.

### Sixth Embodiment

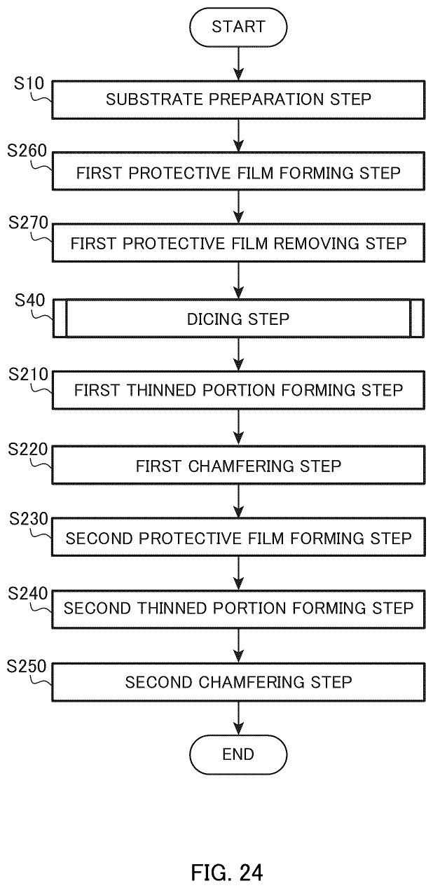

FIG. 24 is a flowchart illustrating a method for manufacturing chips according to a sixth embodiment. The present embodiment shows an example of a process in which the divider mask (protective film 4) and the first protective film 40 described above in the fifth embodiment are formed of the same material, and the first protective film also serves as the divider mask. In the present embodiment, first, a first protective film is formed on the first surface 2 of the substrate 1 in a first protective film forming step (step S260). This first protective film forming step is the same process as the divider mask forming step (step S180) in the fifth embodiment. Next, in a first protective film removing step (step S270), the first protective film is removed along the predetermined dicing lines 5. The first protective film removing step is the same process as the divider mask removing step (step S190) in the fifth embodiment. Next, a dicing step (step S40) is performed to divide the substrate 1 into a plurality of chips 8.

After the dicing step, the first protective film remaining on the first surface 2 is maintained without being removed. Next, a first thinned portion forming step (step S210) is performed to form a first thinned portion (having a shape similar to the first thinned portion 41 shown in FIG. 17) in the remaining first protective film. Steps from the first thinned portion forming step onward (steps S210 through S250) are the same as the corresponding steps S210 through S250 in the fifth embodiment.

According to the method for manufacturing chips of the present embodiment, the protective film (the first protective film) formed on the first surface 2 of the substrate 1 (the chips 8) serves both as a mask for the dicing step and as a mask for the first chamfering step; therefore, the substrate 1 may be divided and the divided chips 8 may be chamfered efficiently.

As a modified example of the sixth embodiment, the order of the dicing step (step S40) and the first thinned portion forming step (step S210) in the flowchart of FIG. 24 may be reversed, such that the first thinned portion forming step is performed before the dicing step.

In a case where the chips 8 are manufactured from the substrate 1 according to the processing order in this modified example, the two laser processing steps, which are the first protective film removing step (step S270) and the first thinned portion forming step (S210), may be performed consecutively. For another example, the first protective film removing step and the first thinned portion forming step may be performed simultaneously. Moreover, using the first protective film having the thinned portion formed therein as a mask, plasma-etching in the dicing step (step S40) and the first chamfering step (S220) may be performed consecutively. As such, according to the modified examples of the embodiment, manufacturing time may be reduced, and production costs may be lowered.

According to the embodiments described above where the method for manufacturing chips of the present disclosure is applied, the substrate 1 is divided along the predetermined dicing lines 5 (dicing step), and the protective films formed on the first surfaces 2 or second surfaces 3 of the divided chips 8 are used as masks for plasma-etching, whereby edge portions in the peripheral regions 80 of the chips 8 are chamfered (chamfering step). Chamfering may improve the strength (durability) of the individual chips 8, prevent the adjacent chips 8 from experiencing excessive stress due to collisions at the edge portions, and suppress damage originating from the edge portions of the chips 8. Further, according to the method for manufacturing chips of the present disclosure, the chips 8 may be chamfered more efficiently than chamfering the individual chips 8 one by one, and productivity of the chips 8 may be improved.

In the methods for manufacturing chips according to the first through fourth embodiments, the chamfering step is performed without applying special treatment on the protective films formed on the first surfaces 2 or the second surfaces 3 of the chips 8, and the time and effort required for preparation may be reduced, and enabling efficient chamfering of the chips.

In the methods for manufacturing chips according to the fifth and sixth embodiments, the chips 8 may be chamfered in the manner that reflects the shape (thickness variation) of the thinned portions formed in the protective film, and the range and shape of chamfering on the first surfaces 2 and second surfaces 3 of the chips 8 may be managed highly accurately. This may enable high-quality chamfering process to the chips 8.

The timing of forming the protective film to be used as a mask in the chamfering step (i.e., the timing of the protective film forming step) may either be before or after the dicing step. For example, in the cases where the protective film serves as the mask to be used in the dicing step and the mask to be used in the chamfering step, such as the protective film 4 formed in the first and second embodiments (the flowcharts in FIGS. 1 and 11), the first protective film formed in the third embodiment (the flowchart in FIG. 12), the protective films formed on the both surfaces in the fourth embodiment (the flowchart in FIG. 13), and the first protective film formed in the sixth embodiment (the flowchart in FIG. 24), the protective film forming step may be performed on the substrate 1 before the dicing step. On the other hand, in the cases where the protective film is not involved in the dicing step (i.e., the protective film not serving as the divider mask), such as the second protective film formed in the third embodiment (the flowchart in FIG. 12), the first protective film 40 and the second protective film 42 formed in the fifth embodiment (the flowchart in FIG. 14), and the second protective film formed in the sixth embodiment (the flowchart in FIG. 24), the protective film forming step may be performed on the divided chips 8 after the dicing step.

In the above-described embodiments, further to performing plasma-etching using the protective film as a mask in the chamfering step, plasma-etching is also used in the dicing step to divide the substrate 1 into the plurality of chips 8. This allows the same apparatus (e.g., the plasma processing apparatus 30) to be shared between the dividing and chamfering steps, and enables rapid transition from the dicing step to the chamfering step, thereby improving production efficiency of the chips 8. Particularly, in the case where the protective film used as a mask in the dicing step also serves as a mask in the chamfering step, plasma-etching in the dicing step and plasma-etching in the chamfering step may be performed consecutively without removing or reforming the protective film between the two steps, and the production efficiency of the chips 8 may be improved remarkably.

In the embodiments described above, examples, in which the substrate 1 is divided into the plurality of chips 8 by plasma-etching from the first surface 2 side where the devices 6 are formed, are shown. However, plasma-etching in the dicing step is not necessarily performed from the first surface 2 side where the devices 6 are formed, but may be performed from the second surface 3 side on the opposite side.

In the embodiments described above, examples, in which SF₆ gas and C₄F₈ gas are used in the dicing step, are shown, but other gases may be used additionally or alternatively to these gases. Moreover, in the embodiments described above, examples, in which SF₆ gas and Ar gas are used in the chamfering step, are shown, but other gases may be used additionally or alternatively to these gasses. Furthermore, in the embodiments described above, an example, in which SF₆ gas is used in the polishing step, is shown, but the other gasses may be used additionally to or alternatively to SF₆ gas.

Meanwhile, the process to divide the substrate 1 in the dicing step is not limited to plasma-etching. For example, in the dicing step, cutting may be performed with a cutting tool (cutting blade) to form the grooves 7 in the substrate 1, laser processing may be performed by irradiating with a laser beam to form the grooves 7 in the substrate 1, or the substrate 1 may be divided by applying external force after forming divide-starting points along the predetermined dicing lines 5. For example, the divide-starting points formed in the substrate 1 may include half-cut grooves to a partial depth in the thickness direction, or modified layers formed inside the thickness of the substrate 1 by laser beam irradiation. Moreover, the method to divide the substrate 1, in which the divide-starting points are formed, by applying external force may include, for example, expand-processing, in which a tape attached to the substrate 1 is expanded; breaking processing, in which pressure is applied near a clamping position while the substrate 1 is clamped on the first surface 2 and the second surface 3; and back grinding, in which the second surface 3 side of the substrate is ground.

For another example, for dividing the substrate 1 in a method other than plasma-etching, a protective film may not be formed on the substrate 1 during the dicing step, but a protective film (for chamfering) may be formed after the substrate 1 has been divided into the plurality of chips 8. In this arrangement, the process does not include the step to remove the protective film along the predetermined dicing lines 5 (the protective film removing step).

Optionally, when the dicing step is performed in a method other than plasma-etching, in order to prevent debris that may be generated when dividing the chips 8 from adhering to the devices 6 and to protect the devices 6 from loads that may be applied during grinding, a protective film may be formed on at least the first surface 2 of the substrate 1. In this arrangement, after the dicing step and after removal of the protective film, a new protective film resistant to plasma-etching (for use as a mask in the chamfering step) may be formed on the chips 8 before proceeding to the chamfering step.

In the embodiments described above, examples in which the peripheral regions 80 of the chips 8 are chamfered on the both surfaces (the first surface 2 and the second surface 3) are described; however, the manufacturing method disclosed herein may also be applied to a case where the peripheral regions 80 of the chips 8 are chamfered solely on a surface on one side. For chamfering the chips 8 solely on the surface on one side, for example, solely the first surface 2 side on which the devices 6 are formed may be chamfered. As such, in particular, strength of the chips 8 may be enhanced in the region around the devices 6 (preventing damage).

For example, when the chips 8 are chamfered solely on the first surface 2 side, in the flowchart of FIG. 12 (the third embodiment), the second protective film forming step (step S110), the second chamfering step (step S120), and the second protective film removing step (step S130) may be omitted, and the remaining steps may be executed. For another example, in the flowchart of FIG. 14 (the fifth embodiment) and the flowchart of FIG. 24 (the sixth embodiment), the second protective film forming step (step S230), the second thinned portion forming step (step S240), and the second chamfering step (step S250) may be omitted, and the remaining steps may be executed.

For another example, for chamfering solely the first surface 2 side of the chips 8, in the chamfering step (step S50) in the flowchart of FIG. 1 (the first embodiment), the first surface 2 side of the chips 8 closer to the gas head 39 may be preferentially chamfered, and the processing conditions may be set so that chamfering is less likely to occur on the second surface 3 side which is farther from the gas head 39, such that plasma-etching is performed under these conditions.

While some embodiments of the present invention have been described, embodiments of the present disclosure may not necessarily be limited to the configurations described above or in the modified example but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure.

As described above, the method for manufacturing chips of the present invention may improve the strength of the divided chips and suppress damage to the chips. Accordingly, the quality and productivity in chip manufacturing may be improved.

What is claimed is:

1. A chip manufacturing method for manufacturing a plurality of chips by dividing a substrate along predetermined dicing lines, comprising:
forming a protective film on a surface of the substrate;
removing the protective film along the predetermined dicing lines;
dividing the substrate into the plurality of chips along the predetermined dicing lines by performing plasma-etching using the protective film remaining on the surface of the substrate as a mask; and
chamfering peripheral regions of the chips by performing plasma-etching using the protective film as a mask.

2. The chip manufacturing method according to claim 1, wherein a condition for plasma-etching in dividing the substrate into the plurality of chips and a condition for plasma-etching in chamfering peripheral regions of the chips are different.

3. The chip manufacturing method according to claim 1, further comprising:
removing a part of the protective film remaining on the surface of the substrate so as to vary a removal amount of the protective film within a plane of the chips in a thickness direction in a manner such that a thickness of the protective film in the peripheral regions decreases from an inner side toward an outer side of each chip, before chamfering peripheral regions of the chips.

4. A chip manufacturing method for manufacturing a plurality of chips by dividing a substrate along predetermined dicing lines, comprising:
dividing the substrate along the predetermined dicing lines to obtain the plurality of chips;
forming a protective film on surfaces of the plurality of chips; and
chamfering peripheral regions of the chips by performing plasma-etching using the protective film as a mask.
